(19) United States
(12) Patent Application Publication
(10) Pub. No.: US 2026/0181989 A1
(43) Pub. Date: Jun. 25, 2026

(54) SEMICONDUCTOR DEVICE

(71) Applicant: Sharp Display Technology Corporation, Kameyama City (JP)

(72) Inventor: Hidetoshi Nakagawa, Kameyama City (JP)

(21) Appl. No.: 19/421,684

(22) Filed: Dec. 16, 2025

(30) Foreign Application Priority Data
Dec. 24, 2024 (JP) 2024-227325

(51) Int. Cl. H10D 64/23; H10D 30/67

(52) U.S. Cl. CPC H10D 64/257; H10D 30/6732

(57) ABSTRACT

A semiconductor device includes a TFT formed on a substrate. The TFT includes a gate electrode formed on the substrate; a gate insulating layer covering the gate electrode; a semiconductor layer formed on the gate insulating layer; and a source electrode and a drain electrode, both formed on the semiconductor layer. When viewed in a normal direction of the substrate, the semiconductor layer is formed over the gate electrode. The source electrode and the drain electrode are arranged on the semiconductor layer in such a manner as to have mutually facing parallel sides spaced apart by a gap of length L therebetween. The semiconductor layer includes, in the gap, a first portion having a width W0 orthogonal to a direction of the length L, and a second portion having a width W1 greater than W0. At least a part of the second portion is located in the gap.

### BACKGROUND

### 1. Field

The present disclosure relates to a semiconductor device including a thin film transistor (TFT), and, for example, to an active matrix substrate including a thin film transistor provided in a liquid crystal display device or the like.

### 2. Description of the Related Art

Bottom-gate-type TFTs are widely adopted as TFTs of an active matrix substrate included in a liquid crystal display device. As the resolution of liquid crystal display devices becomes finer, TFTs become smaller. For example, as a liquid crystal display device having a multi-pixel structure in order to improve gradation display characteristics (γ characteristics) at an oblique viewing angle, a liquid crystal display device in which each pixel includes three TFTs is known (for example, Japanese Unexamined Patent Application Publication No. 2006-276411). A pixel having a multi-pixel structure includes a bright sub-pixel configured to display a higher gradation than would otherwise be displayed and a dark sub-pixel configured to display a lower gradation than would otherwise be displayed. As will be described later, among the three TFTs, the first and second TFTs switch on/off the connection between the bright sub-pixel and the dark sub-pixel and the source bus line, and the third TFT switches on/off the connection between the dark sub-pixel and a buffer capacitance (see FIG. 1). The third TFT is often smaller than the first and second TFTs.

In a small TFT, such as the third TFT in a liquid crystal display device with the above-described multi-pixel structure, source-drain leakage may occasionally occur. The smaller the TFT, the more likely source-drain leakage is to occur, without being limited to the above-described third TFT, of course.

The present disclosure provides a semiconductor device including a TFT in which the occurrence of source-drain leakage is suppressed.

### SUMMARY

According to a certain embodiment of the present disclosure, a semiconductor device stated in Item below is provided.

### Item 1

A semiconductor device includes a substrate, and a thin-film transistor (TFT) formed on the substrate. The TFT includes a gate electrode formed on the substrate; a gate insulating layer covering the gate electrode; a semiconductor layer formed on the gate insulating layer; and a source electrode and a drain electrode, both formed on the semiconductor layer. When viewed in a normal direction of the substrate, the semiconductor layer is formed over the gate electrode. The source electrode and the drain electrode are arranged on the semiconductor layer in such a manner as to have mutually facing parallel sides spaced apart by a gap of length L therebetween. The semiconductor layer includes, in the gap, a first portion having a width W0 orthogonal to a direction of the length L, and a second portion having a width W1 greater than W0. At least a part of the second portion is located in the gap.

### BRIEF DESCRIPTION OF THE DRAWINGS

FIG. 1 is an equivalent circuit diagram of one pixel having a multi-pixel structure of a liquid crystal display device;

FIG. 2A is a schematic plan view for explaining an issue arising in a TFT included in an active matrix substrate according to a comparative example;

FIG. 2B is a schematic cross-sectional view of the TFT taken along the line IIB-IIB in FIG. 2A;

FIG. 3A is a schematic plan view of a TFT included in an active matrix substrate according to an embodiment of the present disclosure;

FIG. 3B is a schematic cross-sectional view of the TFT taken along the line IIIB-IIIB in FIG. 3A;

FIG. 3C is a schematic plan view of a TFT included in an active matrix substrate according to an embodiment of the present disclosure;

FIG. 3D is a schematic cross-sectional view of the TFT taken along the line IIID-IIID in FIG. 3C;

FIG. 4 is a schematic plan view of a TFT included in an active matrix substrate according to an embodiment of the present disclosure;

FIG. 5 is a schematic plan view of a TFT included in an active matrix substrate according to an embodiment of the present disclosure;

FIG. 6 is a schematic plan view of a TFT included in an active matrix substrate according to an embodiment of the present disclosure;

FIG. 7 is a schematic plan view of a TFT included in an active matrix substrate according to an embodiment of the present disclosure;

FIG. 8 is a schematic plan view of a TFT included in an active matrix substrate according to an embodiment of the present disclosure;

FIG. 9 is a schematic plan view of a TFT included in an active matrix substrate according to an embodiment of the present disclosure;

FIG. 10 is a schematic plan view of a TFT included in an active matrix substrate according to an embodiment of the present disclosure;

FIG. 11 is a schematic plan view of a TFT included in an active matrix substrate according to an embodiment of the present disclosure;

FIG. 12 is a schematic plan view of a TFT included in an active matrix substrate according to an embodiment of the present disclosure;

FIG. 13 is a schematic plan view of a TFT included in an active matrix substrate according to an embodiment of the present disclosure; and

FIG. 14 is a schematic plan view of a TFT included in an active matrix substrate according to an embodiment of the present disclosure.

### DESCRIPTION OF THE EMBODIMENTS

With reference to the accompanying drawings, a semiconductor device according to some embodiments of the present disclosure will be described below. The semiconductor device according to some embodiments of the present disclosure can be, for example, an active matrix substrate of a liquid crystal display device. Although an active matrix substrate will be taken as an example of a semiconductor device below, the semiconductor device according to some embodiments of the present disclosure is not limited to the active matrix substrate disclosed by way of example below.

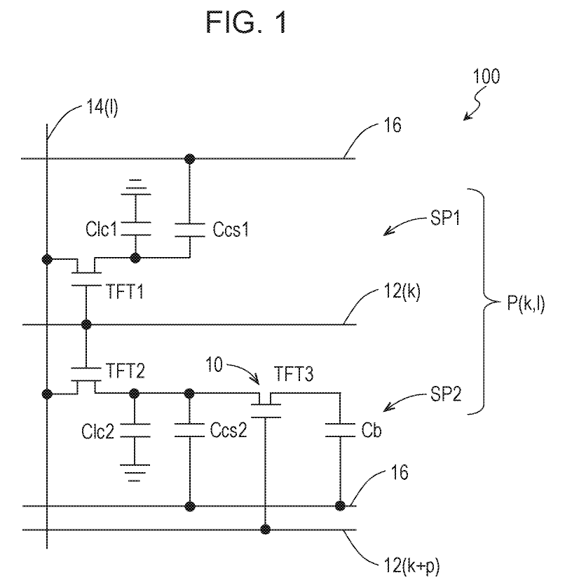

FIG. 1 is an equivalent circuit diagram of one pixel P of a liquid crystal display device 100 that includes pixels P with a multi-pixel structure. The pixel P illustrated therein is a pixel P(k,l) in the k-th row and l-th column among a plurality of pixels P arranged in a matrix of m rows and n columns. For the purpose of improving gradation display characteristics (γ characteristics) at an oblique viewing angle, the pixel P having a multi-pixel structure includes a first sub-pixel (bright sub-pixel) SP1 configured to display a higher gradation than would otherwise be displayed and a second sub-pixel (dark sub-pixel) SP2 configured to display a lower gradation than would otherwise be displayed.

A liquid crystal display device in which each pixel having a multi-pixel structure has three TFTs, such as the liquid crystal display device 100 illustrated in FIG. 1, is disclosed in, for example, Japanese Unexamined Patent Application Publication No. 2006-276411. The entire contents of disclosure in Japanese Unexamined Patent Application Publication No. 2006-276411 are incorporated herein by reference.

Among the three TFTs of the pixel P(k,l), two TFTs, more specifically, TFT1 and TFT2, switch on/off the connection between the sub-pixel electrode of the first sub-pixel SP1 and a source bus line 14(l), and the sub-pixel electrode of the second sub-pixel SP2 and the source bus line 14(l), respectively. For example, the drain electrode of the TFT1 is connected to the first sub-pixel electrode of the first sub-pixel SP1, and the drain electrode of the TFT2 is connected to the second sub-pixel electrode of the second sub-pixel SP2. The first sub-pixel electrode and the second sub-pixel electrode are each disposed so as to face a common electrode (counter electrode) with a liquid crystal layer interposed therebetween, thereby forming a liquid crystal capacitance Clc1 and a liquid crystal capacitance Clc2, respectively. In parallel with the liquid crystal capacitance Clc1 and the liquid crystal capacitance Clc2, an auxiliary capacitance Ccs1 and an auxiliary capacitance Ccs2, which correspond thereto respectively, are provided. The liquid crystal capacitance Clc1 and the auxiliary capacitance Ccs1 constitute a first sub-pixel capacitance, and the liquid crystal capacitance Clc2 and the auxiliary capacitance Ccs2 constitute a second sub-pixel capacitance. One electrode of each of the auxiliary capacitances Ccs1 and Ccs2 is connected to an auxiliary capacitance line 16, and the same voltage as that of the common electrode is supplied thereto.

The gate electrode of the TFT1 and the gate electrode of the TFT2 are connected to a common gate bus line 12(k). The source electrode of the TFT1 and the source electrode of the TFT2 are connected to the common source bus line 14(l). TFT3, the third one, switches on/off the connection between the buffer capacitance electrode of a buffer capacitance Cb and the second pixel electrode. The gate electrode of the TFT3 is connected to, for example, a gate bus line 12(k+p), which is located p rows after the gate bus line 12(k), to which the gate electrode of the TFT1 and the gate electrode of the TFT2 are connected (where p is a positive integer).

The TFT1, TFT2, and TFT3 are simultaneously turned on by a gate-on pulse included in a gate scanning signal supplied to the common gate bus line 12(k), and a display signal voltage supplied to the common source bus line 14(l) is applied to the first sub-pixel electrode and the second sub-pixel electrode. After the TFT1 and the TFT2 are turned off, the TFT3 is turned on, and the second sub-pixel electrode and the buffer capacitance electrode become connected to each other. Since the liquid crystal capacitance Clc2 including the second sub-pixel electrode becomes connected to the buffer capacitance Cb including the buffer capacitance electrode, the charge stored in the liquid crystal capacitance Clc2 moves to the buffer capacitance Cb. As a result, the voltage held by the liquid crystal capacitance Clc2 drops, and the second sub-pixel SP2 behaves as a dark pixel.

The above-described source-drain leakage is most likely to occur in the TFT3, the smallest of the three TFTs, namely the TFT1, TFT2, and TFT3, which are included in the active matrix substrate of the liquid crystal display device 100 having such a configuration. The active matrix substrate of the liquid crystal display device 100 according to a certain embodiment of the present disclosure can include, as the TFT3, for example, any of TFTs 10A to 10L, which will be described later.

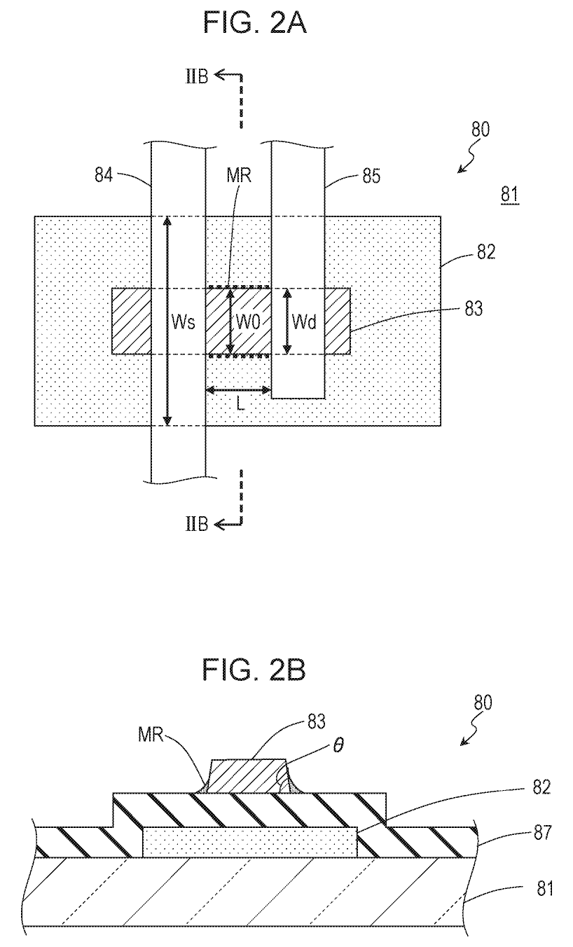

With reference to FIGS. 2A and 2B, the reason why the above-described source-drain leakage tends to occur in the small TFT3 will be explained.

FIG. 2A is a schematic plan view for explaining an issue arising in a TFT 80 included in an active matrix substrate according to a comparative example. FIG. 2B is a schematic cross-sectional view of the TFT 80 taken along the line IIB-IIB in FIG. 2A.

The TFT 80 is formed on a substrate (for example, a glass substrate) 81, and includes a gate electrode 82 formed on the substrate 81, a gate insulating layer 87 (see FIG. 2B) covering the gate electrode 82, a semiconductor layer 83 formed on the gate insulating layer 87, and a source electrode 84 and a drain electrode 85 both formed on the semiconductor layer 83. When viewed in the normal direction of the substrate 81, the semiconductor layer 83 is formed over the gate electrode 82, and the source electrode 84 and the drain electrode 85 are arranged on the semiconductor layer 83 in such a manner as to have mutually facing parallel sides spaced apart by a gap of length L (hereinafter sometimes referred to as an "S-D gap") therebetween. The source electrode 84 is a part of a source bus line and extends in the vertical direction in the figure.

For example, the gate electrode 82, a gate bus line, and an auxiliary capacitance line are formed of a gate metal layer having a thickness of 580 nm (for example, titanium (Ti), copper (Cu)). The gate insulating layer 87 is formed of, for example, an insulating layer having a thickness of 410 nm (for example, silicon nitride (SiNx)). The semiconductor layer 83 is formed of, for example, a semiconductor layer having a thickness of 220 nm (for example, amorphous silicon). The source electrode 84, the source bus line, and the drain electrode 85 are formed of a source metal layer having a thickness of 550 nm (for example, titanium (Ti), copper (Cu)). The patterning of each layer is performed by means of a known photolithography process, using wet etching or dry etching.

The semiconductor layer 83 has a constant width W0 orthogonal to the direction of the length L. The width Wd of the portion, of the drain electrode 85, overlapping with the semiconductor layer 83 (sometimes referred to as the width Wd of the drain electrode 85) is equal to the width W0 of the semiconductor layer 83, and the width Ws of the portion, of the source electrode 84, overlapping with the gate electrode 82 is greater than the width W0 of the semiconductor layer 83 and the width Wd of the drain electrode 85. By forming the gate electrode 82 larger than the semiconductor layer 83 in a plan view and forming the semiconductor layer 83 over the gate electrode 82, it is possible to, for example, prevent light coming from a backlight from entering the semiconductor layer 83 (in particular, the channel region), or at least suppress it.

When the TFT 80 is small, that is, when the area of the semiconductor layer 83 is small (for example, 100 µm² or less), during the process of forming the source electrode 84 and the drain electrode 85 by patterning the source metal layer, a residue MR of the source metal may sometimes remain along the edge (length L) of the semiconductor layer 83 lying in the S-D gap. When there exists such a residue MR of the source metal, and, in addition, if the length L of the edge of the semiconductor layer 83 lying in the S-D gap is short (for example, 5.0 µm or less), source-drain leakage is likely to occur.

As illustrated in FIG. 2B, when a semiconductor layer 83 having a small area is formed, due to various factors, the edge of the semiconductor layer 83 tends to be steep. For example, an angle θ formed between the side surface of the semiconductor layer 83 and the surface of the gate insulating layer 87 (sometimes referred to as a "taper angle") in this case is, for example, 70° or more and 80° or less, and the residue MR of the source metal tends to remain along the edge of the semiconductor layer 83.

A way to suppress the above-described source-drain leakage is to increase the length L of the edge of the semiconductor layer 83 lying in the S-D gap, and/or to make the taper angle θ of the side surface of the semiconductor layer 83 lying in the S-D gap less than 70°, or preferably, 50° or less. The lower limit of the taper angle θ is not particularly limited, but is, for example, 40° or more. If the area of the semiconductor layer 83 is increased so as to reduce the taper angle θ of the side surface of the semiconductor layer 83, there arises a problem that the capacitance formed between the semiconductor layer 83 and the gate electrode 82 increases. The increase in the capacitance between the semiconductor layer 83 and the gate electrode 82 could cause a decrease in display quality.

As will be described in detail below with reference to the drawings, a TFT included in an active matrix substrate according to an embodiment of the present disclosure includes, in the S-D gap (length L) between the mutually facing parallel sides of the source electrode and the drain electrode, a first portion having a width W0 orthogonal to the direction of the length L, and a second portion having a width W1 greater than W0, wherein at least a part of the second portion is located in the S-D gap. The portion that is a part of the second portion and protrudes beyond the first portion will sometimes be referred to as a "protrusion". Since, in the S-D gap, there exists the second portion where the width of the semiconductor layer is W1, which is greater than W0, the length of the edge of the semiconductor layer lying in the S-D gap is greater than L, and as a result, the occurrence of source-drain leakage is suppressed. Furthermore, by making the angle θ formed between the side surface defining the width W1 of the second portion and the surface of the gate insulating layer less than 70°, it is possible to suppress the residue MR of the source metal from remaining along the edge of the second portion of the semiconductor layer 83 lying in the S-D gap. As a result, the occurrence of source-drain leakage is suppressed. In the TFT included in the semiconductor device according to an embodiment of the present disclosure, since only the width of the second portion of the semiconductor layer is large, the increase in the area of the semiconductor layer is limited, and thus the increase in the capacitance between the semiconductor layer and the gate electrode is suppressed.

With reference to the accompanying drawings, examples of a TFT 10 (see FIG. 1) included in an active matrix substrate according to some embodiments of the present disclosure will be described below. In the drawings referred to below, the same reference signs will be assigned to components having the same function, and an explanation of them will sometimes be omitted.

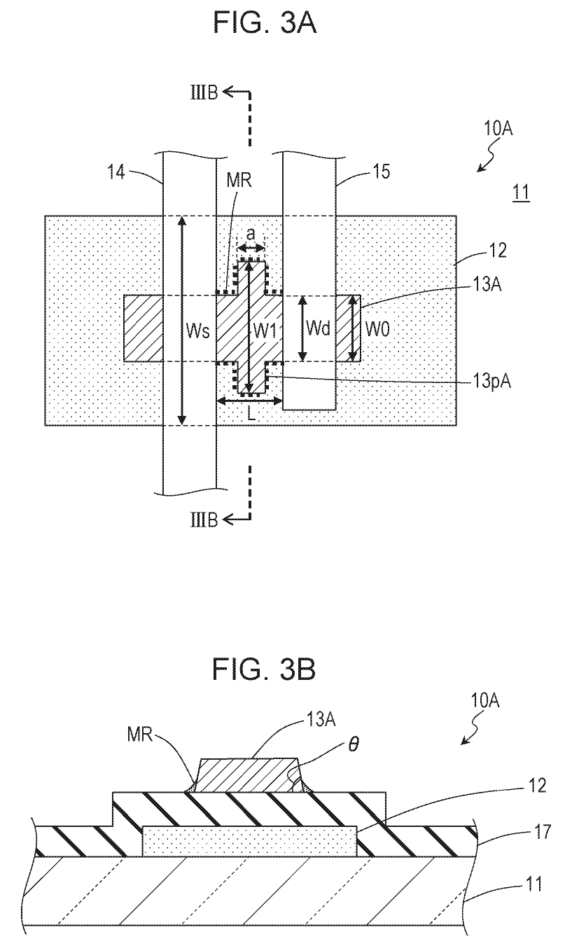

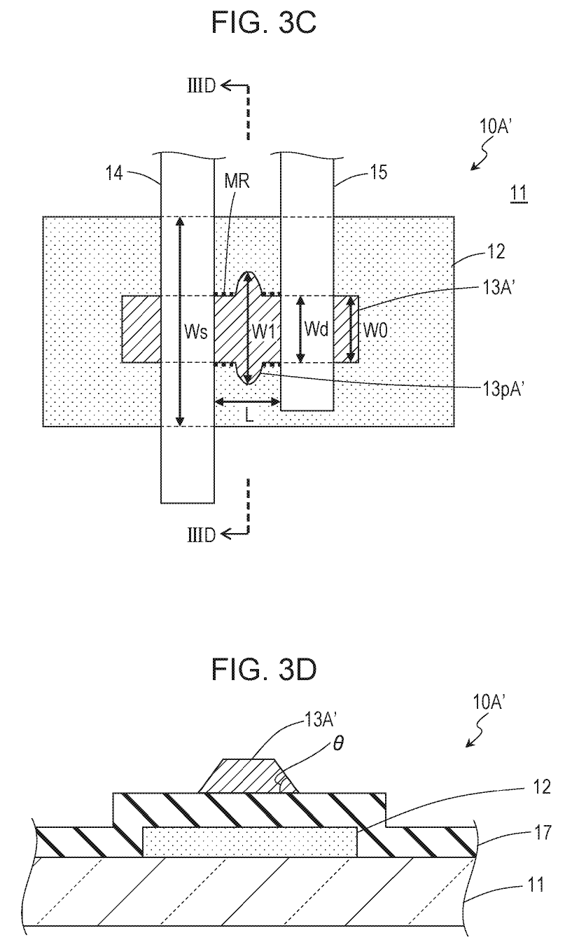

FIG. 3A is a schematic plan view of a TFT 10A included in an active matrix substrate according to an embodiment of the present disclosure. FIG. 3B is a schematic cross-sectional view of the TFT 10A taken along the line IIIB-IIIB in FIG. 3A. FIGS. 3A and 3B illustrate an example in which a semiconductor layer 13A is patterned to conform to a mask pattern by means of a photolithography process.

The TFT 10A is formed on a substrate (for example, a glass substrate) 11, and includes a gate electrode 12 formed on the substrate 11, a gate insulating layer 17 (see FIG. 3B) covering the gate electrode 12, a semiconductor layer 13A formed on the gate insulating layer 17, and a source electrode 14 and a drain electrode 15 both formed on the semiconductor layer 13A. When viewed in the normal direction of the substrate 11, the semiconductor layer 13A is formed over the gate electrode 12, and the source electrode 14 and the drain electrode 15 are arranged on the semiconductor layer 13A in such a manner as to have mutually facing parallel sides spaced apart by a gap of length L therebetween. The source electrode 14 is a part of a source bus line and extends in the vertical direction in the figure. The thickness and the constituent materials of each layer of the TFT 10A may be the same as those of each layer of the TFT 80 described earlier with reference to FIGS. 2A and 2B.

The semiconductor layer 13A includes, in the S-D gap, a first portion having a width W0 orthogonal to the direction of the length L, and a second portion having a width W1 greater than W0. The second portion includes two protrusions 13pA protruding beyond the first portion. The length of the protrusion 13pA in the direction of the width W1 is h, and the length thereof in the direction of the length L is "a". Therefore, it holds that W1 = W0 + 2h. Since the entire second portion is located in the S-D gap, when the length of the edge of the semiconductor layer 13A lying in the S-D gap is defined as L1, L1 = L + 2h, meaning that L1 is greater than L. Therefore, in the TFT 10A, the occurrence of source-drain leakage is suppressed.

The length L1 of the edge of the semiconductor layer 13A lying in the S-D gap is, for example, 1.1 times or more and 3 times or less of L. The width "a" of the protrusion may be less than the length L of the S-D gap (for example, 6.0 µm), for example, about L - 2 µm (e.g., 4 µm).

When the semiconductor layer 13A is patterned to conform to a mask pattern by means of a photolithography process, as illustrated in FIG. 3B, the edge of the semiconductor layer 13A is formed with a steep profile, and the angle θ (the taper angle θ) formed between its side surface and the surface of the gate insulating layer 17 is, for example, 70° or more and 80° or less. Accordingly, as in the TFT 80 according to the comparative example described above, the residue MR of the source metal may sometimes exist along the edge of the semiconductor layer 13A lying in the S-D gap. However, in the TFT 10A, since the length of the edge of the semiconductor layer 13A lying in the S-D gap is greater than the length L of the S-D gap, the occurrence of source-drain leakage is suppressed.

In the process of manufacturing the TFT 10A illustrated in FIGS. 3A and 3B, if the semiconductor layer 13A is excessively etched, a TFT 10A′ illustrated in FIGS. 3C and 3D is obtained. As illustrated in FIG. 3C, the lengths a′ and h′ of the protrusion 13pA′ of the second portion of the semiconductor layer 13A′ are less than the lengths "a" and h of the protrusion 13pA of the second portion of the semiconductor layer 13A illustrated in FIG. 3A, respectively. Since the protrusions 13pA of the second portion of the semiconductor layer 13A are minute, they are likely to be shaved off by physical and chemical processes such as etching and cleaning, which weakens their upper parts, resulting in making them relatively gentle in slope. Accordingly, the semiconductor layer 13A′ having been subjected to excessive etching, as illustrated in FIG. 3D, has gently sloped edges, and the angle θ (the taper angle θ) formed between the side surface of the semiconductor layer 13A′ and the surface of the gate insulating layer 17 is less than 70° (for example, 40° or more and 50° or less). Therefore, the residue MR of the source metal is less likely to remain along at least the edge of the protrusion 13pA′ of the semiconductor layer 13A′. In this case, a′ and h′ may be any values as long as they are greater than 0 µm.

Cases where a semiconductor layer is patterned to conform to a mask pattern by means of a photolithography process will mainly be described below. However, in any case, the semiconductor layer, particularly the protrusion, may sometimes be over-etched.

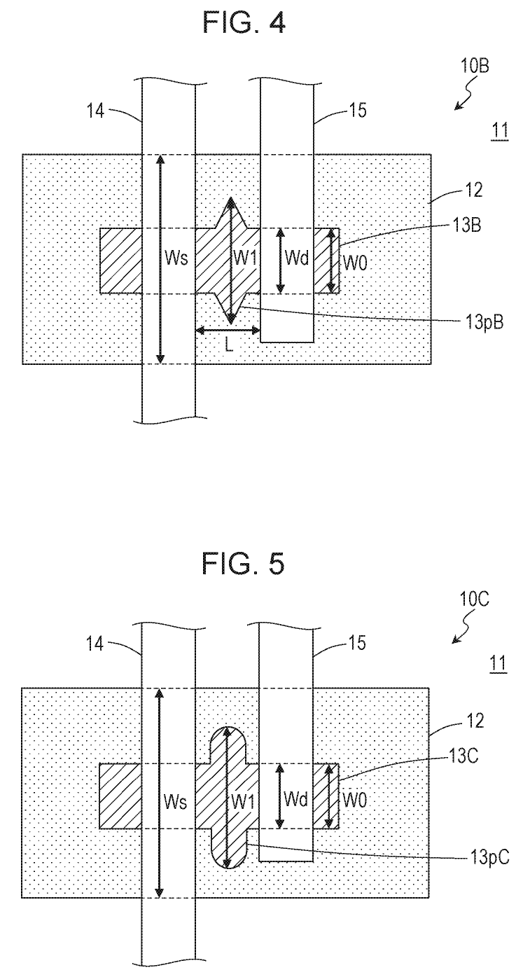

The semiconductor layer 13A of the TFT 10A illustrated in FIG. 3A includes the protrusions 13pA each having a rectangular shape in the S-D gap. However, as in a semiconductor layer 13B of a TFT 10B illustrated in FIG. 4, it may include protrusions 13pB each having a triangular shape in the S-D gap. Alternatively, as in a semiconductor layer 13C of a TFT 10C illustrated in FIG. 5, it may include protrusions 13pC each having a curved (for example, arc-shaped) outline in the S-D gap.

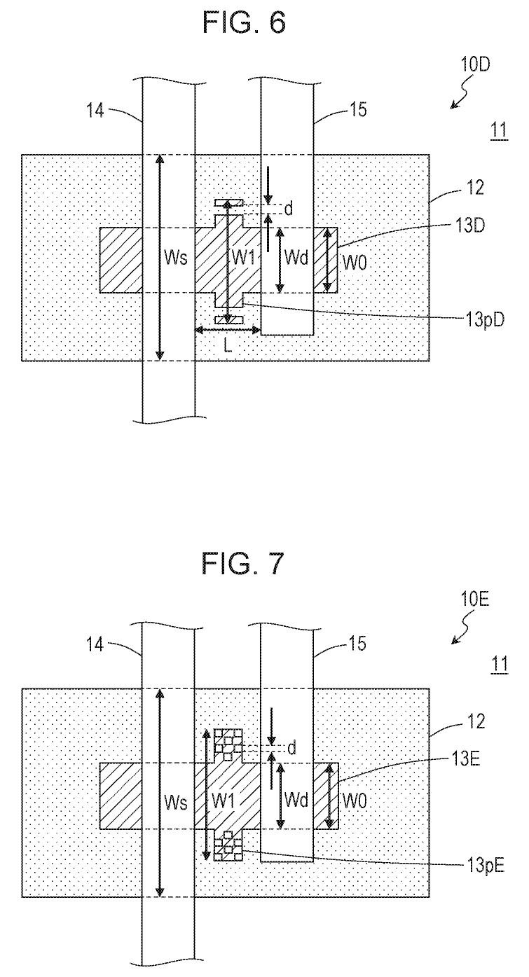

As in a semiconductor layer 13D of a TFT 10D illustrated in FIG. 6, one or more slits may be formed in each protrusion 13pD in the S-D gap, or as in a semiconductor layer 13E of a TFT 10E illustrated in FIG. 7, a plurality of holes may be formed in each protrusion 13pE in the S-D gap. The width d of the slit or the length d of one side of the hole is, for example, 0.5 µm or more and 2 µm or less. Such protrusions having slits or holes are easily over-etched. Therefore, an effect of reducing the taper angle of the protrusion is more easily obtained.

For example, when a protrusion is formed in the S-D gap as in that of the semiconductor layer 13A illustrated in FIG. 3A, if the length L of the S-D gap is small, the width "a" of the protrusion could be approximately equal to L; due to variations in patterning accuracy or the like, if the width "a" of the protrusion becomes greater than L, the width (channel width) of the semiconductor layer 13A in the S-D gap becomes W1, resulting in an increase in an on-current of the TFT. Moreover, since the length of the edge of the semiconductor layer 13A in the S-D gap becomes equal to L, it is not possible to suppress the occurrence of leakage between the source and the drain.

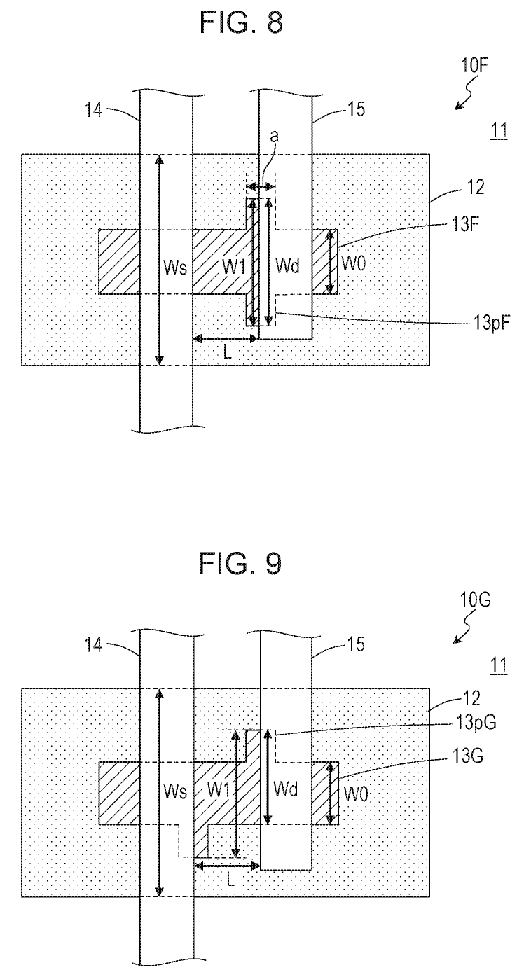

In order to avoid the above problem, in a TFT included in an active matrix substrate according to another embodiment of the present disclosure, the second portion includes a portion overlapping with at least one of the drain electrode or the source electrode. Specific configurations will be described below with reference to FIGS. 8 to 11.

As in a semiconductor layer 13F of a TFT 10F illustrated in FIG. 8, when a protrusion 13pF has a portion overlapping (partially overlapping) with the drain electrode 15, even if the width "a" of the protrusion 13pF becomes large, the protrusion 13pF is never located over the entire S-D gap. Therefore, the width of the semiconductor layer 13F is substantially W0, and the increase in the on-current is thus suppressed. Although an example has been shown here in which a part of the protrusion 13pF is located in such a way as to overlap with the drain electrode 15, the protrusion 13pF may be located in such a way as to overlap with the source electrode 14.

As in a semiconductor layer 13G of a TFT 10G illustrated in FIG. 9, it may include a protrusion 13pG having a portion overlapping (partially overlapping) with the drain electrode 15, and a protrusion 13pG having a portion overlapping (partially overlapping) with the source electrode 14.

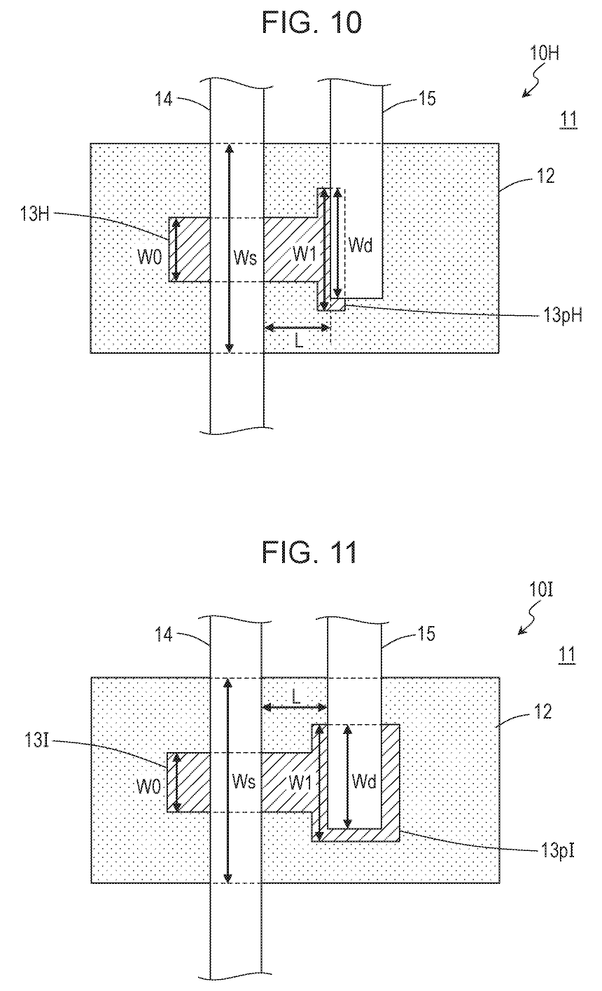

As in a semiconductor layer 13H of a TFT 10H illustrated in FIG. 10 or a semiconductor layer 13I of a TFT 10I illustrated in FIG. 11, by embracing the lower end portion of the drain electrode 15 with semiconductor layers 13H, 13I, and thus by making the width W1 of the protrusion 13pH of the semiconductor layer 13H or the protrusion 13pI of the semiconductor layer 13I larger than the width Wd of the drain electrode 15, it is possible to increase the length of the lower edge of the semiconductor layers 13H, 13I, and it is therefore possible to further suppress the occurrence of source-drain leakage.

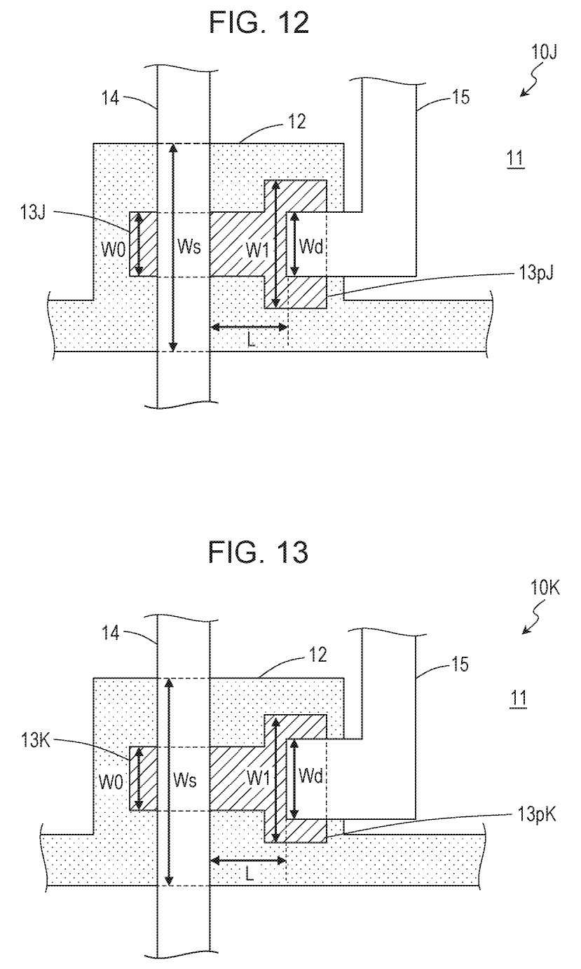

As in a TFT 10J illustrated in FIG. 12, in a case where the tip portion of the drain electrode 15 overlapping with the protruding portion 13pJ of a semiconductor layer 13J is made perpendicular to the extending direction of the source electrode 14, that is, parallel to the direction of the length L of the S-D gap, the width of the TFT 10J is defined by the width W0 of the semiconductor layer 13J on the source electrode 14 side and defined by the width Wd of the drain electrode 15 on the drain electrode 15 side, and, by this means, it is possible to make the width Wd of the drain electrode 15 substantially equal to the width W0 of the first portion of the semiconductor layer 13J.

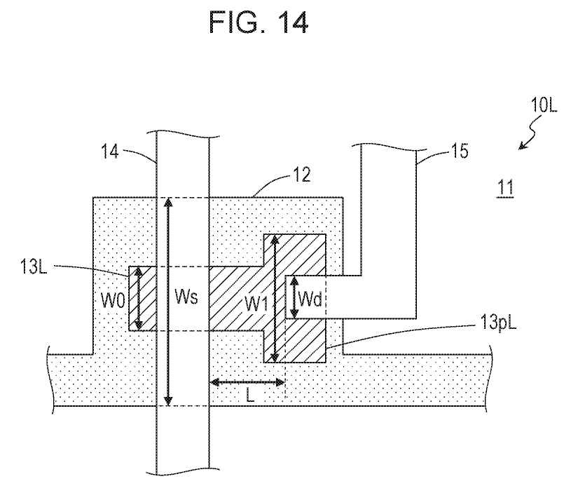

For example, as in a TFT 10K illustrated in FIG. 13, when the width Wd of the drain electrode 15 overlapping with the protruding portion 13pK of a semiconductor layer 13K is greater than the width W0 of the first portion of the semiconductor layer 13K, the influence of the line of electric force from the portion (corner portion) where the width Wd of the drain electrode 15 is greater than W0 is large. Alternatively, as in a TFT 10L illustrated in FIG. 14, when the width Wd of the drain electrode 15 overlapping with the protruding portion 13pL of a semiconductor layer 13L is less than the width W0 of the first portion of the semiconductor layer 13L, the influence of the line of electric force from the portion (corner portion) where the width Wd of the drain electrode 15 is less than W0 is large. Therefore, as illustrated in FIG. 12, the width Wd of the drain electrode 15 may be configured to be substantially equal to the width W0 of the first portion of the semiconductor layer 13J.

A semiconductor device according to an embodiment of the present disclosure can be suitably applied to, for example, an active matrix substrate of a liquid crystal display device.

The present disclosure contains subject matter related to that disclosed in Japanese Priority Patent Application JP 2024-227325 filed in the Japan Patent Office on December 24, 2024, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor device comprising:
a substrate; and
a thin-film transistor formed on the substrate, and including
a gate electrode formed on the substrate;
a gate insulating layer covering the gate electrode;
a semiconductor layer formed on the gate insulating layer; and
a source electrode and a drain electrode, both formed on the semiconductor layer, wherein
when viewed in a normal direction of the substrate, the semiconductor layer is formed over the gate electrode,
the source electrode and the drain electrode are arranged on the semiconductor layer in such a manner as to have mutually facing parallel sides spaced apart by a gap of length L therebetween,
the semiconductor layer includes, in the gap, a first portion having a width W0 orthogonal to a direction of the length L, and a second portion having a width W1 greater than W0, and
at least a part of the second portion is located in the gap.

2. The semiconductor device according to claim 1, wherein
when viewed in the normal direction of the substrate, the second portion includes a portion overlapping with at least one of the drain electrode or the source electrode.

3. The semiconductor device according to claim 1, wherein
the second portion includes a portion overlapping with the drain electrode, and
the width W1 of the second portion is greater than a width Wd of the drain electrode.

4. The semiconductor device according to claim 3, wherein
the width Wd of the drain electrode is substantially equal to the width W0 of the first portion.

5. The semiconductor device according to claim 1, wherein
an entirety of the second portion is located in the gap.

6. The semiconductor device according to claim 1, wherein
an angle θ formed between a side surface defining the width W1 of the second portion and a surface of the gate insulating layer is less than 70°.

7. The semiconductor device according to claim 5, wherein
a portion, of the second portion, protruding beyond the first portion in a width direction includes a triangular portion.

8. The semiconductor device according to claim 5, wherein
a portion, of the second portion, protruding beyond the first portion in a width direction includes an arc-shaped portion.

9. The semiconductor device according to claim 5, wherein
a portion, of the second portion, protruding beyond the first portion in a width direction includes a slit.

10. The semiconductor device according to claim 5, wherein
a portion, of the second portion, protruding beyond the first portion in a width direction includes a plurality of holes.
